(19) United States
(12) Patent Application Publication
(10) Pub. No.: US 2026/0113016 A1
(43) Pub. Date: Apr. 23, 2026

(54) SURFACE ACOUSTIC WAVE DEVICE

(71) Applicant: WISOL CO., LTD., Gyeonggi-do (KR)

(72) Inventors: Chang Min LEE, Gyeonggi-do (KR); Yoshikazu Kihara, Gyeonggi-do (KR); Tae Hyun Kim, Gyeonggi-do (KR)

(21) Appl. No.: 19/347,287

(22) Filed: Oct. 1, 2025

(30) Foreign Application Priority Data
Oct. 18, 2024 (KR) 10-2024-0142713

(51) Int. Cl. H03H 9/145; H03H 9/02

(52) U.S. Cl. CPC H03H 9/14541; H03H 9/02992

(57) ABSTRACT

Disclosed is a surface acoustic wave (SAW) device including a piezoelectric substrate, and an IDT electrode layer formed on the piezoelectric substrate. The IDT electrode layer includes: an adhesive layer for bonding to the piezoelectric substrate; a first electrode diffusion layer formed on the adhesive layer; a first alloy forming layer formed on the first electrode diffusion layer; a main electrode layer formed on the first alloy forming layer; a second alloy forming layer formed on the main electrode layer; a second electrode diffusion layer formed on the second alloy forming layer; and a connection layer formed on the second electrode diffusion layer.

### CROSS-REFERENCE TO RELATED APPLICATION

This application claims priority from Korean Patent Application No. 10-2024-0142713 filed on Oct. 18, 2024 in the Korean Intellectual Property Office, the contents of which in its entirety are herein incorporated by reference.

### FIELD

The present disclosure relates to a surface acoustic wave (SAW) device.

### BACKGROUND

A surface acoustic wave (SAW) device is configured to generate acoustic waves that propagate along the surface of an elastic substrate. These acoustic waves are generated from an electrical signal as a result of the piezoelectric effect, and when the electric field of the acoustic waves is concentrated near the surface of the substrate, they may interact with the conduction electrons of another semiconductor disposed directly above the surface. The medium through which the acoustic waves propagate is a piezoelectric material having a high electromechanical coupling coefficient and low acoustic wave energy loss, and the semiconductor has a high conduction electron mobility and optimal resistivity, with a low DC power requirement to ensure optimal efficiency. The SAW device serves as an electromechanical element that substitutes for an electronic circuit by utilizing the interaction between the surface acoustic waves and semiconductor conduction electrons.

These SAW devices are not only used in various communication applications, but also serve as key components for mobile phones and base stations. The most commonly used types of SAW devices are passband filters and resonators. Due to the low cost, small size, and excellent technical parameters (such as low loss and selectivity), SAW devices possess a significantly greater competitive advantage over devices based on other physical principles.

In particular, recent applications of SAW devices require high filtering performance along with a low insertion loss, and accordingly, various attempts have been made to reduce the insertion loss. However, conventional methods for reducing the insertion loss involve techniques such as adjusting the spacing between electrodes or using a plurality of SAW devices.

However, in the case of these SAW devices, a plurality of electrode layers forming the IDT electrode fail within about 1100 hours at a temperature of 125° C. and a power of 29 dBm, indicating a vulnerability to high temperature and high power durability.

### SUMMARY

The present disclosure provides a surface acoustic wave (SAW) device having high heat resistance and high power durability.

In one aspect of the present disclosure, a surface acoustic wave (SAW) device includes a piezoelectric substrate, and an IDT electrode layer formed on the piezoelectric substrate. The IDT electrode layer includes: an adhesive layer for bonding to the piezoelectric substrate; a first electrode diffusion layer formed on the adhesive layer; a first alloy forming layer formed on the first electrode diffusion layer; a main electrode layer formed on the first alloy forming layer; a second alloy forming layer formed on the main electrode layer; a second electrode diffusion layer formed on the second alloy forming layer; and a connection layer formed on the second electrode diffusion layer.

Each of the first electrode diffusion layer and the second electrode diffusion layer may be formed of any one material selected from the group consisting of copper (Cu), magnesium (Mg), and silver (Ag), or an alloy thereof.

The main electrode layer may be formed of any one material selected from the group consisting of copper (Cu), aluminum (AI), and platinum (Pt), or an alloy thereof.

Each of the first alloy forming layer and the second alloy forming layer may be formed of an alloy including at least one of copper (Cu), magnesium (Mg), and silver (Ag), and at least one of aluminum (Al) and platinum (Pt).

Each of the first electrode diffusion layer, the second electrode diffusion layer, and the main electrode layer may have an average thickness satisfying the following Equation:

$$0.05 \leq ( Td 1 + Td 2 ) / Tm \leq 0.18 \qquad [ Equation ]$$

where Td1 denotes an average thickness of the first electrode diffusion layer, Td2 denotes an average thickness of the second electrode diffusion layer, and Tm denotes an average thickness of the main electrode layer.

In another aspect, a surface acoustic wave (SAW) device includes a piezoelectric substrate, and an IDT electrode layer formed on the piezoelectric substrate. The IDT electrode layer includes: an adhesive layer for bonding to the piezoelectric substrate; an electrode diffusion layer formed on the adhesive layer; an alloy forming layer formed on the electrode diffusion layer; a first main electrode layer formed on the alloy forming layer; an electrode diffusion suppression layer formed on the first main electrode layer; a second main electrode layer formed on the electrode diffusion suppression layer; and a connection layer formed on the second main electrode layer.

The electrode diffusion layer may be formed of any one material selected from the group consisting of copper (Cu), magnesium (Mg), and silver (Ag), or an alloy thereof.

Each of the first main electrode layer and the second main electrode layer may be formed of any one material selected from the group consisting of copper (Cu), aluminum (Al), and platinum (Pt), or an alloy thereof.

The alloy forming layer may be formed of an alloy including at least one of copper (Cu), magnesium (Mg), and silver (Ag), and at least one of aluminum (Al) and platinum (Pt).

The electrode diffusion suppression layer may be formed of any one material selected from the group consisting of chromium (Cr), titanium (Ti), nickel (Ni), zirconium (Zr), and titanium nitride (TiN), or an alloy thereof.

Each of the first main electrode layer, the second main electrode layer, and the electrode diffusion suppression layer may have an average thickness satisfying the following Equation:

$$0.04 \leq ( Tb ) / ( Tm 1 + Tm 2 ) \leq 0.15 \qquad [ Equation ]$$

where Tm1 denotes an average thickness of the first main electrode layer, Tm2 denotes an average thickness of the second main electrode layer, and Tb denotes an average thickness of the electrode diffusion suppression layer.

In yet another aspect, a surface acoustic wave (SAW) device includes a piezoelectric substrate, and an IDT electrode layer formed on the piezoelectric substrate. The IDT electrode layer includes: an adhesive layer for bonding to the piezoelectric substrate; a first electrode diffusion layer formed on the adhesive layer; a first alloy forming layer formed on the first electrode diffusion layer; a first main electrode layer formed on the first alloy forming layer; an electrode diffusion suppression layer formed on the first main electrode layer; a second main electrode layer formed on the electrode diffusion suppression layer; a second alloy forming layer formed on the second main electrode layer; a second electrode diffusion layer formed on the second alloy forming layer; and a connection layer formed on the second electrode diffusion layer.

Each of the first electrode diffusion layer and the second electrode diffusion layer may be formed of any one material selected from the group consisting of copper (Cu), magnesium (Mg), and silver (Ag), or an alloy thereof.

Each of the first main electrode layer and the second main electrode layer may be formed of any one material selected from the group consisting of copper (Cu), aluminum (Al), and platinum (Pt), or an alloy thereof.

Each of the first alloy forming layer and the second alloy forming layer may be formed of an alloy including at least one of copper (Cu), magnesium (Mg), and silver (Ag), and at least one of aluminum (Al) and platinum (Pt).

The electrode diffusion suppression layer may be formed of any one material selected from the group consisting of chromium (Cr), titanium (Ti), nickel (Ni), zirconium (Zr), and titanium nitride (TiN), or an alloy thereof.

Each of the first main electrode layer, the second main electrode layer, and the electrode diffusion suppression layer may have an average thickness satisfying the following Equation:

$$0.04 \leq ( Tb ) / ( Tm 1 + Tm 2 ) \leq 0.15 \qquad [ Equation ]$$

where Tm1 denotes an average thickness of the first main electrode layer, Tm2 denotes an average thickness of the second main electrode layer, and Tb denotes an average thickness of the electrode diffusion suppression layer.

### BRIEF DESCRIPTION OF THE DRAWINGS

FIG. 1 shows the structure of a SAW device according to the first embodiment of the present disclosure.

FIG. 2 is a reference diagram illustrating the formation of a first alloy forming layer by applying heat to a contact surface between a first electrode diffusion layer and a main electrode layer.

FIG. 3 is a comparison of the lifetime of a SAW device according to the first embodiment of the present disclosure with a conventional technology.

FIG. 4 shows the structure of a SAW device according to a second embodiment of the present disclosure.

FIG. 5 is a comparison of the lifetime of a SAW device according to the second embodiment of the present disclosure with a conventional technology.

FIG. 6 shows the structure of a SAW device according to a third embodiment of the present disclosure.

### DETAILED DESCRIPTION

The terminology used herein is for the purpose of describing embodiments only and is not intended to limit the present disclosure. In this specification, the singular forms are intended to include the plural forms unless the context clearly indicates otherwise.

In this specification, the terms “include” and “comprise,” and variations thereof, are intended to specify the presence of stated features, integers, steps, operations, elements, or components, but do not preclude the presence or addition of one or more other features, integers, steps, operations, elements, components, or groups thereof. In addition, the embodiments described herein will be explained with reference to cross-sectional views and/or plan views, which are schematic examples of the present disclosure. Accordingly, embodiments of the present disclosure are not limited to the specific forms shown, but also include various modifications and variations. Therefore, the regions illustrated in the drawings are schematic in nature, and the shapes of the illustrated regions are intended to depict specific forms of regions of the device and are not intended to limit the scope of the present disclosure.

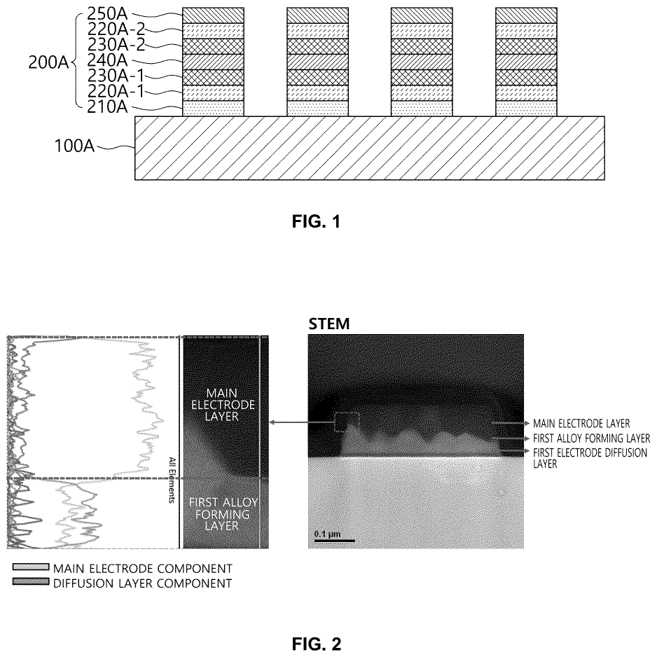

FIG. 1 shows the structure of a surface acoustic wave (SAW) device according to the first embodiment of the present disclosure.

A piezoelectric substrate 100A may be formed of a material capable of providing a piezoelectric effect. For example, the piezoelectric substrate 100A may be one of a silicon substrate, a diamond substrate, a sapphire substrate, a silicon carbide substrate, a LiNbO3 substrate, and a LiTaO3 substrate.

An IDT electrode layer 200A is formed on the piezoelectric substrate 100A, with a plurality of electrode layers arranged alternately at regular intervals along a horizontal direction.

As illustrated in FIG. 1, the IDT electrode layer 200A includes an adhesive layer 210A, a first electrode diffusion layer 220A-1, a first alloy forming layer 230A-1, a main electrode layer 240A, a second alloy forming layer 230A-2, a second electrode diffusion layer 220A-2, and a connection layer 250A.

The adhesive layer 210A is a layer for bonding each layer of the IDT electrode layer 200A to the piezoelectric substrate 100A. The adhesive layer 210A is formed on the piezoelectric substrate 100A.

The adhesive layer 210A may be formed of at least one material selected from the group consisting of titanium, aluminum oxide (Al2O3), titanium nitride (TiN), chromium (Cr), zirconium (Zr), hafnium oxide (HfO2), titanium oxide (TiO2), and tantalum pentoxide (Ta2O5).

The first electrode diffusion layer 220A-1 is formed on the adhesive layer 210A, and disposed beneath the main electrode layer 240A to reinforce the strength of the main electrode layer 240A.

The first electrode diffusion layer 220A-1 may be formed of any one material selected from the group consisting of copper (Cu), magnesium (Mg), and silver (Ag), or an alloy thereof.

The first alloy forming layer 230A-1 is formed on the first electrode diffusion layer 220A-1. The first alloy forming layer 230A-1 is a layer alloyed by heat applied to a contact surface between the first electrode diffusion layer 220A-1 and the main electrode layer 240A.

FIG. 2 is a reference diagram illustrating formation of the first alloy forming layer 230A-1 by applying heat to a contact surface between the first electrode diffusion layer 220A-1 and the main electrode layer 240A.

In order to achieve heat diffusion at the interface between the first electrode diffusion layer 220A-1 and the main electrode layer 240A, heat treatment is applied for 1 hour or more at a high temperature (e.g., 200° C. or higher) that is equal to or lower than the melting temperature of a metal material. After the heat treatment, the structure is slowly cooled to remove internal stress. A first alloy forming layer 230A-1 is formed by heat treatment, causing distortion in a crystal lattice and thereby hindering movement of dislocations.

The first alloy forming layer 230A-1 may be formed of an alloy including at least one of copper (Cu), magnesium (Mg), and silver (Ag), and at least one of aluminum (Al) and platinum (Pt).

The main electrode layer 240A is a layer formed on the first alloy forming layer 230A-1. The main electrode layer 240A may be formed of any one material selected from the group consisting of copper (Cu), aluminum (Al), and platinum (Pt), or an alloy thereof.

The second alloy forming layer 230A-2 is formed on the main electrode layer 240A. The second alloy forming layer 230A-2 is a layer alloyed by heat applied to a contact surface between the second electrode diffusion layer 220A-2 formed on the second alloy forming layer 230A-2 and the main electrode layer 240A.

The second alloy forming layer 230A-2 may be formed of an alloy including at least one of copper (Cu), magnesium (Mg), and silver (Ag), and at least one of aluminum (Al) and platinum (Pt).

The second electrode diffusion layer 220A-2 is formed on the second alloy forming layer 230A-2, and disposed over the main electrode layer 240A to reinforce the strength of the main electrode layer 240A.

The second electrode diffusion layer 220A-2 may be formed of any one material selected from the group consisting of copper (Cu), magnesium (Mg), and silver (Ag), or an alloy thereof.

The connection layer 250A is formed on the second electrode diffusion layer 220A-2 to connect a wiring layer formed on the connection layer 250A with the IDT electrode layer 200A.

The average thickness of the first electrode diffusion layer 220A-1, the second electrode diffusion layer 220A-2, and the main electrode layer 240A may satisfy the following Equation 1.

$$0.05 \leq ( Td 1 + Td 2 ) / Tm \leq 0.18 \qquad [ Equation 1 ]$$

In Equation 1, Td1 denotes an average thickness of the first electrode diffusion layer 220A-1, Td2 denotes an average thickness of the second electrode diffusion layer 220A-2, and Tm denotes an average thickness of the main electrode layer 240A.

The thicker the main electrode layer 240A, the alloy forming layer of high strength must be maintained at a greater thickness. If (Td1+Td2)/Tm is lower than 0.05, it fails to provide a minimum alloy forming layer thickness sufficient to prevent fracture. Meanwhile, as the alloy forming layer thickens, the power durability characteristics are enhanced, but the electrical characteristics deteriorate. Accordingly, in order to secure a minimum thickness to prevent deterioration of electrical characteristics while ensuring the required power durability characteristics, (Td1+Td2)/Tm must be lower than 0.18.

Therefore, in order to secure a sufficient alloy forming layer thickness necessary for strengthening the main electrode layer 240A while minimizing deterioration of the electrical characteristics of the product, it is necessary to satisfy 0.05≤(Td1+Td2)/Tm≤0.18.

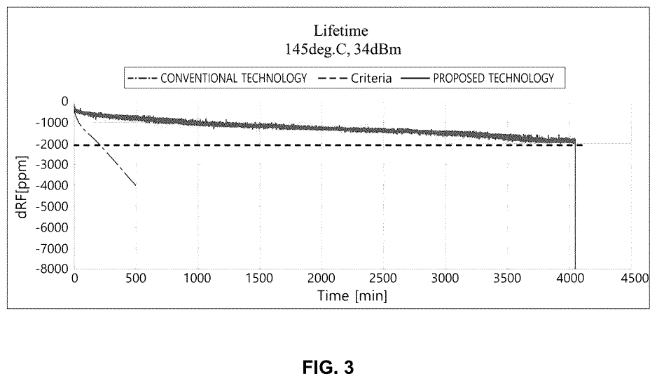

FIG. 3 compares the lifetime of a SAW device according to the first embodiment of the present disclosure with a conventional technology.

Referring to FIG. 3, it can be seen that at a temperature of 145° C. and a power of 34 dBm, the SAW device according to the first embodiment of the present disclosure has a lifetime of 4000 minutes, which is significantly longer than the 500 minutes of a conventional technology.

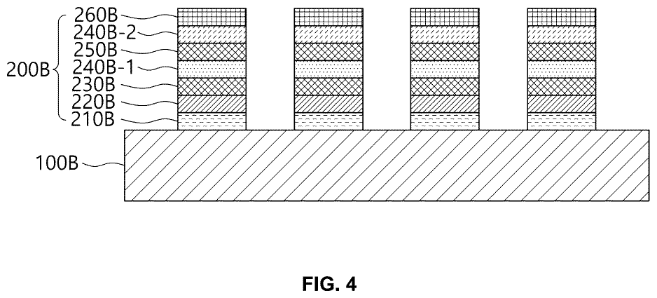

FIG. 4 shows the structure of a SAW device according to a second embodiment of the present disclosure.

A piezoelectric substrate 100B may be one of a silicon substrate, a diamond substrate, a sapphire substrate, a silicon carbide substrate, a LiNbO3 substrate, and a LiTaO3 substrate.

An IDT electrode layer 200B is formed on the piezoelectric substrate 100B, with a plurality of electrode layers arranged alternately at regular intervals along a horizontal direction.

As illustrated in FIG. 4, the IDT electrode layer 200B includes an adhesive layer 210B, an electrode diffusion layer 220B, an alloy forming layer 230B, a first main electrode layer 240B-1, an electrode diffusion suppression layer 250B, a second main electrode layer 240B-2, and a connection layer 260B.

The adhesive layer 210B is a layer for bonding each layer forming the IDT electrode layer 200B to the piezoelectric substrate 100B. The adhesive layer 210B is formed on the piezoelectric substrate 100B.

The adhesive layer 210B may be formed of at least one material selected from the group consisting of titanium, aluminum oxide (Al2O3), titanium nitride (TiN), chromium (Cr), zirconium (Zr), hafnium oxide (HfO2), titanium oxide (TiO2), and tantalum pentoxide (Ta2O5).

The electrode diffusion layer 220B is formed on the adhesive layer 210B, and disposed beneath the first main electrode layer 240B-1 to reinforce the strength of the first main electrode layer 240B-1.

The electrode diffusion layer 220B may be formed of any one material selected from the group consisting of copper (Cu), magnesium (Mg), and silver (Ag), or an alloy thereof.

The alloy forming layer 230B is formed on the electrode diffusion layer 220B. The alloy forming layer 230B is a layer alloyed by heat applied to a contact surface between the electrode diffusion layer 220B and the first main electrode layer 240B-1.

This alloy forming layer 230B may be formed of an alloy including at least one of copper (Cu), magnesium (Mg), and silver (Ag), and at least one of aluminum (Al) and platinum (Pt).

The first main electrode layer 240B-1 is a layer formed on the alloy forming layer 230B. The first main electrode layer 240B-1 may be formed of any one material selected from the group consisting of copper (Cu), aluminum (Al), and platinum (Pt), or an alloy thereof.

The electrode diffusion suppression layer 250B is formed on the first main electrode layer 240B-1 to prevent metal ejection and diffusion due to damage to the first main electrode layer 240B-1 or the second main electrode layer 240B-2.

To this end, the electrode diffusion suppression layer 250B may be formed of any one material selected from the group consisting of chromium (Cr), titanium (Ti), nickel (Ni), zirconium (Zr), and titanium nitride (TiN), or an alloy thereof.

The second main electrode layer 240B-2 is formed on the electrode diffusion suppression layer 250B. The second main electrode layer 240B-2 may be formed of any one material selected from the group consisting of copper (Cu), aluminum (Al), and platinum (Pt), or an alloy thereof.

The connection layer 260B is formed on the second main electrode layer 240B-2 to connect a wiring layer formed on the connection layer 260B with the IDT electrode layer 200B.

An average thickness of each of the first main electrode layer 240B-1, the second main electrode layer 240B-2, and the electrode diffusion suppression layer 250B may satisfy Equation 2.

$$0.04 \leq ( Tb ) / ( Tm 1 + Tm 2 ) \leq 0.15 \qquad [ Equation 2 ]$$

In Equation 2, Tm1 denotes an average thickness of the first main electrode layer 240B-1, Tm2 denotes an average thickness of the second main electrode layer 240B-2, and Tb denotes an average thickness of the electrode diffusion suppression layer 250B.

The electrode diffusion suppression layer 250B must have a thickness of not less than 0.04, which is required as a minimum thickness for functioning as an electrode diffusion suppression layer when the thickness of the first main electrode layer 240B-1 or the second main electrode layer 240B-2 increases.

In addition, as the thickness of the electrode diffusion suppression layer 250B increases, the deterioration of the electrical characteristics of the first main electrode layer 240B-1 or the second main electrode layer 240B-2 becomes more significant. Accordingly, in order to prevent diffusion while avoiding deterioration of electrical characteristics, the thickness ratio (Tb)/(Tm1+Tm2) must be less than 0.15.

Therefore, in order to secure a sufficient thickness for diffusion prevention while minimizing deterioration of the electrical characteristics of a product, it is necessary to satisfy 0.04≤(Tb)/(Tm1+Tm2)≤0.15.

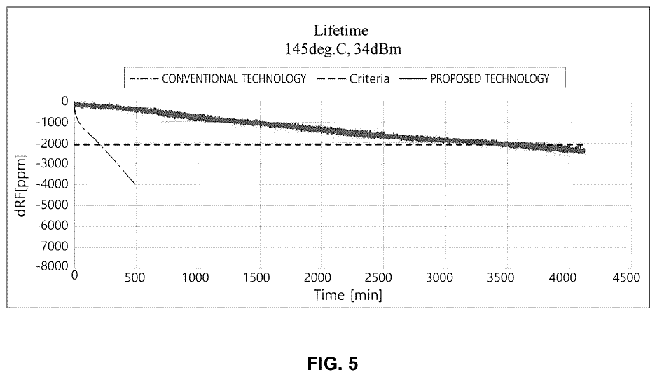

FIG. 5 compares the lifetime of a SAW device according to the second embodiment of the present disclosure with that of a device of the related technology.

Referring to FIG. 5, it can be seen that, at a temperature of 145 [° C.] and a power of 34 [dBm], the SAW device according to the second embodiment of the present disclosure has a lifetime (3800 [min]) that is significantly longer than the lifetime (500 [min]) of a device of the related technology.

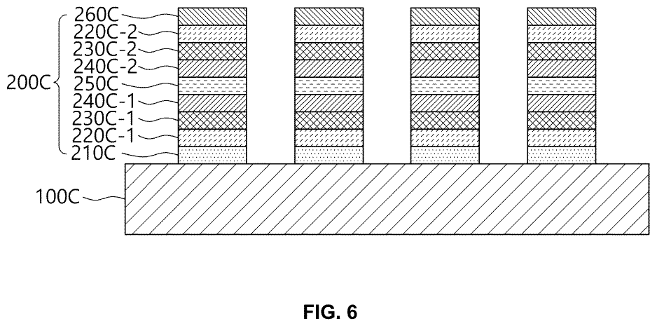

FIG. 6 shows the structure of a SAW device according to a third embodiment of the present disclosure.

A piezoelectric substrate 100C may be one of a silicon substrate, a diamond substrate, a sapphire substrate, a silicon carbide substrate, a LiNbO3 substrate, and a LiTaO3 substrate.

An IDT electrode layer 200C is formed on the piezoelectric substrate 100C, with a plurality of electrode layers arranged alternately at regular intervals along a horizontal direction.

As illustrated in FIG. 6, the IDT electrode layer 200C includes an adhesive layer 210C, a first electrode diffusion layer 220C-1, a first alloy forming layer 230C-1, a first main electrode layer 240C-1, an electrode diffusion suppression layer 250C, a second main electrode layer 240C-2, a second alloy forming layer 230C-2, a second electrode diffusion layer 220C-2, and a connection layer 260C.

The adhesive layer 210C is a layer for bonding each layer forming the IDT electrode layer 200C to the piezoelectric substrate 100C. The adhesive layer 210C is formed on the piezoelectric substrate 100C.

The adhesive layer 210C may be formed of at least one material selected from the group consisting of titanium, aluminum oxide (Al2O3), titanium nitride (TiN), chromium (Cr), zirconium (Zr), hafnium oxide (HfO2), titanium oxide (TiO2), and tantalum pentoxide (Ta2O5).

The first electrode diffusion layer 220C-1 is formed on the adhesive layer 210C, and disposed beneath the first main electrode layer 240C-1 to reinforce the strength of the first main electrode layer 240C-1.

The first electrode diffusion layer 220C-1 may be formed of any one material selected from the group consisting of copper (Cu), magnesium (Mg), and silver (Ag), or an alloy thereof.

The first alloy forming layer 230C-1 is formed on the first electrode diffusion layer 220C-1. The first alloy forming layer 230C-1 is a layer alloyed by heat applied to a contact surface between the first electrode diffusion layer 220C-1 and the first main electrode layer 240C-1.

The first alloy forming layer 230C-1 may be formed of an alloy including at least one of copper (Cu), magnesium (Mg), and silver (Ag), and at least one of aluminum (Al) and platinum (Pt).

The first main electrode layer 240C-1 is formed on the first alloy forming layer 230C-1. The first main electrode layer 240C-1 may be formed of any one material selected from the group consisting of copper (Cu), aluminum (Al), and platinum (Pt), or an alloy thereof.

The electrode diffusion suppression layer 250C is formed on the first main electrode layer 240C-1 to prevent metal ejection and diffusion due to damage to the first main electrode layer 240C-1 or the second main electrode layer 240C-2.

The electrode diffusion suppression layer 250C may be formed of any one material selected from the group consisting of chromium (Cr), titanium (Ti), nickel (Ni), zirconium (Zr), and titanium nitride (TiN), or an alloy thereof.

The second main electrode layer 240C-2 is formed on the electrode diffusion suppression layer 250C. The second main electrode layer 240C-2 may be formed of any one material selected from the group consisting of copper (Cu), aluminum (Al), and platinum (Pt), or an alloy thereof.

The second alloy forming layer 230C-2 is formed on the second main electrode layer 240C-2. The second alloy forming layer 230C-2 is a layer alloyed by heat applied to a contact surface between the second electrode diffusion layer 220C-2 and the second main electrode layer 240C-2.

The second alloy forming layer 230C-2 may be formed of an alloy including at least one of copper (Cu), magnesium (Mg), and silver (Ag), and at least one of aluminum (Al) and platinum (Pt).

The second electrode diffusion layer 220C-2 is formed on the second alloy forming layer 230C-2, and disposed over the second main electrode layer 240C-2 to reinforce the strength of the second main electrode layer 240C-2.

The second electrode diffusion layer 220C-2 may be formed of any one material selected from the group consisting of copper (Cu), magnesium (Mg), and silver (Ag), or an alloy thereof.

The connection layer 260C is formed on the second electrode diffusion layer 220C-2 to connect a wiring layer formed on the connection layer 260C with the IDT electrode layer 200C.

An average thickness of each of the first main electrode layer 240C-1, the second main electrode layer 240C-2, and the electrode diffusion suppression layer 250C may satisfy Equation 3 as below:

$$0.04 \leq ( Tb ) / ( Tm 1 + Tm 2 ) \leq 0.15 \qquad [ Equation 3 ]$$

In Equation 3, Tm1 denotes an average thickness of the first main electrode layer 240C-1, Tm2 denotes an average thickness of the second main electrode layer 240C-2, and Tb denotes an average thickness of the electrode diffusion suppression layer 250C.

According to the present disclosure, for the IDT electrode layer of a SAW device, a first electrode diffusion layer and a second electrode diffusion layer may be formed between main electrode layers, or an electrode diffusion suppression layer may be formed between the first main electrode layer and the second main electrode layer, so as to provide the IDT electrode of the SAW device with high heat resistance and high power durability. Accordingly, the SAW device of the present disclosure may extend the lifetime of the SAW device by increasing the durability of the electrode compared to the related technology.

Although the technical idea of the present disclosure has been described above with reference to the accompanying drawings, this is merely an example of preferred embodiments of the present disclosure and is not intended to limit the scope of the present disclosure.

Therefore, the present disclosure is not limited to the specific preferred embodiments described above, and various modifications may be made by those skilled in the art without departing from the spirit and scope of the present disclosure as defined by the appended claims, and such modifications are intended to fall within the scope of the appended claims.

What is claimed is:

1. A surface acoustic wave (SAW) device comprising:
a piezoelectric substrate, and
an IDT electrode layer formed on the piezoelectric substrate, wherein the IDT electrode layer comprises:
an adhesive layer for bonding to the piezoelectric substrate;
a first electrode diffusion layer formed on the adhesive layer;
a first alloy forming layer formed on the first electrode diffusion layer;
a main electrode layer formed on the first alloy forming layer;
a second alloy forming layer formed on the main electrode layer;
a second electrode diffusion layer formed on the second alloy forming layer; and
a connection layer formed on the second electrode diffusion layer.

2. The SAW device of claim 1, wherein each of the first electrode diffusion layer and the second electrode diffusion layer is formed of any one material selected from the group consisting of copper (Cu), magnesium (Mg), and silver (Ag), or an alloy thereof.

3. The SAW device of claim 1, wherein the main electrode layer is formed of any one material selected from the group consisting of copper (Cu), aluminum (Al), and platinum (Pt), or an alloy thereof.

4. The SAW device of claim 1, wherein each of the first alloy forming layer and the second alloy forming layer is formed of an alloy comprising at least one of copper (Cu), magnesium (Mg), and silver (Ag), and at least one of aluminum (Al) and platinum (Pt).

5. The SAW device of claim 1, wherein an average thickness of each of the first electrode diffusion layer, the second electrode diffusion layer, and the main electrode layer satisfies the following Equation:
$$0.05 \leq ( Td 1 + Td 2 ) / Tm \leq 0.18 \qquad [ Equation ]$$
where Td1 denotes an average thickness of the first electrode diffusion layer, Td2 denotes an average thickness of the second electrode diffusion layer, and Tm denotes an average thickness of the main electrode layer.

6. A surface acoustic wave (SAW) device comprising:
a piezoelectric substrate, and
an IDT electrode layer formed on the piezoelectric substrate, wherein the IDT electrode layer comprises:
an adhesive layer for bonding to the piezoelectric substrate;
an electrode diffusion layer formed on the adhesive layer;
an alloy forming layer formed on the electrode diffusion layer;
a first main electrode layer formed on the alloy forming layer;
an electrode diffusion suppression layer formed on the first main electrode layer;
a second main electrode layer formed on the electrode diffusion suppression layer; and
a connection layer formed on the second main electrode layer.

7. The SAW device of claim 6, wherein the electrode diffusion layer is formed of any one material selected from the group consisting of copper (Cu), magnesium (Mg), and silver (Ag), or an alloy thereof.

8. The SAW device of claim 6, wherein each of the first main electrode layer and the second main electrode layer is formed of any one material selected from the group consisting of copper (Cu), aluminum (Al), and platinum (Pt), or an alloy thereof.

9. The SAW device of claim 6, wherein the alloy forming layer is formed of an alloy comprising at least one of copper (Cu), magnesium (Mg), and silver (Ag), and at least one of aluminum (Al) and platinum (Pt).

10. The SAW device of claim 6, wherein the electrode diffusion suppression layer is formed of any one material selected from the group consisting of chromium (Cr), titanium (Ti), nickel (Ni), zirconium (Zr), and titanium nitride (TiN), or an alloy thereof.

11. The SAW device of claim 6, wherein an average thickness of each of the first main electrode layer, the second main electrode layer, and the electrode diffusion suppression layer satisfies the following Equation:
$$0.04 \leq ( Tb ) / ( Tm 1 + Tm 2 ) \leq 0.15 \qquad [ Equation ]$$
where Tm1 denotes an average thickness of the first main electrode layer, Tm2 denotes an average thickness of the second main electrode layer, and Tb denotes an average thickness of the electrode diffusion suppression layer.

12. A surface acoustic wave (SAW) device comprising:
a piezoelectric substrate, and
an IDT electrode layer formed on the piezoelectric substrate, wherein the IDT electrode layer comprises:
an adhesive layer for bonding to the piezoelectric substrate;
a first electrode diffusion layer formed on the adhesive layer;
a first alloy forming layer formed on the first electrode diffusion layer;
a first main electrode layer formed on the first alloy forming layer;
an electrode diffusion suppression layer formed on the first main electrode layer;
a second main electrode layer formed on the electrode diffusion suppression layer;
a second alloy forming layer formed on the second main electrode layer;
a second electrode diffusion layer formed on the second alloy forming layer; and
a connection layer formed on the second electrode diffusion layer.

13. The SAW device of claim 12, wherein each of the first electrode diffusion layer and the second electrode diffusion layer is formed of any one material selected from the group consisting of copper (Cu), magnesium (Mg), and silver (Ag), or an alloy thereof.

14. The SAW device of claim 12, wherein each of the first main electrode layer and the second main electrode layer is formed of any one material selected from the group consisting of copper (Cu), aluminum (AI), and platinum (Pt), or an alloy thereof.

15. The SAW device of claim 12, wherein each of the first alloy forming layer and the second alloy forming layer is formed of an alloy comprising at least one of copper (Cu), magnesium (Mg), and silver (Ag), and at least one of aluminum (Al) and platinum (Pt).

16. The SAW device of claim 12, wherein the electrode diffusion suppression layer is formed of any one material selected from the group consisting of chromium (Cr), titanium (Ti), nickel (Ni), zirconium (Zr), and titanium nitride (TiN), or an alloy thereof.

17. The SAW device of claim 12, wherein an average thickness of each of the first main electrode layer, the second main electrode layer, and the electrode diffusion suppression layer satisfies the following Equation:
$$0.04 \leq ( Tb ) / ( Tm 1 + Tm 2 ) \leq 0.15 \qquad [ Equation ]$$
where Tm1 denotes an average thickness of the first main electrode layer, Tm2 denotes an average thickness of the second main electrode layer, and Tb denotes an average thickness of the electrode diffusion suppression layer.
